(19) United States
(12) Patent Application Publication
(10) Pub. No.: US 2026/0333619 A1
(43) Pub. Date: Oct. 22, 2026

(54) AIRFLOW DEVICES

(71) Applicant: Telefonaktiebolaget LM Ericsson (publ), Stockholm (SE)

(72) Inventors: Claudio D’INCÀ, Genova (IT); Sergio MOSTI, Genova (IT)

(21) Appl. No.: 19/122,563

(22) PCT Filed: Nov. 2, 2022
(86) PCT No.: PCT/EP2022/080589

§ 371 Date: Apr. 18, 2025

(51) Int. Cl. H05K 7/20; B01D 46/00; B01D 46/44; B01D 46/46

(52) U.S. Cl. CPC H05K 7/20209; B01D 46/0047; B01D 46/0086; B01D 46/444; B01D 46/448; B01D 46/46; B01D 2273/30; B01D 2279/45

(57) ABSTRACT

Embodiments described herein relate to methods and apparatus for monitoring flow devices. In one aspect there is provided a method that includes driving a first airflow device at a predetermined level to generate an airflow through the first airflow device and out of electronic equipment having a particulate filter, monitoring an airflow through a second airflow device into the electronic equipment, and generating an indication of a performance characteristic of the particulate filter based on the monitoring of the airflow through the second airflow device.

### TECHNICAL FIELD

The present disclosure relates to thermal management for electronic devices such as telecommunications equipment including radio fronthaul and backhaul units and optical node and an optical transceiver. The present disclosure also relates to methods and apparatus for monitoring airflow devices such as cooling fans to indicate the status of particulate filters in the electronic devices.

### BACKGROUND

Telecommunication equipment such as Radio access nodes are thermally managed with fan trays that ensure proper airflow around electronic components to dissipation of heat generated by their operation. Multiple fans are used to avoid a single point of failure and are also required by the ANSI/ETSI standards. In case of a single “Fan Failure”, the other fans must ensure the node survival until fan tray replacement. Multiple fans also ensure more uniform distribution of the airflow across the electronic components. Each fan provides a contribution to the overall airflow (m³/s) and to the air pressure. The electronic components provide resistance to airflow so each fan contributes to overall air pressure to ensure adequate airflow inside the radio access note.

In order to avoid electronic component failure or safety issues such as fires, particulate filtering of the airflows is used to prevent dust accumulation on the electronic components. However, particulate filters may become clogged over time, reducing airflow and therefore reducing heat dissipation from the electronic components. This may result in electronic component failure or even fires within the node. Therefore, particulate filter replacement is necessary to retore proper thermal management. This may be especially challenging for remote radio access nodes where technicians are required to replace particulate filters in the field.

Current solutions to this problem include the addition of thermal sensors in each radio access node to measure temperatures in several places. This requires characterization at different ambient temperatures and airflows to determine calibration profiles which may then be used to detect increased temperature due to limited airflow because of clogged particulate filters. However, this adds to the hardware required for the node as well as its complexity of operation.

Air speed meters (anemometers) may be used to determine airflow speed and infer from this reduced airflow due to particulate filter clogging. However, these components are relatively large electro-mechanical devices which increase the size of the radio access nodes and also limit their “mean time before failure” (MTBF) so that they need to be replaceable in the field. This complicates the overall design, cost and mechanical complexity of the radio access node.

### SUMMARY

According to a first aspect of the present disclosure, there is provided a method of monitoring airflow devices. The method comprises driving a first said airflow device (120a) at a predetermined level to generate an airflow through the first said airflow device and out of electronic equipment having a particulate filter, monitoring an airflow through a second airflow device into the electronic equipment, and generating an indication of a performance characteristic of the particulate filter based on the monitoring of the airflow through the second airflow device.

In some examples, the second airflow device is not driven to generate airflow out of the electronic equipment. In some examples, the airflow devices may be fans with tachometer signal outputs. In some examples, the indication of a performance characteristic of the particulate filter may be a level of occlusion of the particulate filter.

This approach provides a number of advantages including providing a simple cost effective solution to the problem of detecting particulate filter clogging. This may avoid fitting additional hardware to detect particulate filter clogging in electronic equipment. For example, this functionality may be implemented using a simple software update on existing hardware. Existing fan functionality such as a tachometer signal may be easily integrated.

According to a second aspect of the present disclosure, there is provided an apparatus for monitoring airflow devices in electronic equipment. The apparatus comprises a processor and a memory. The memory contains instructions executable by the processor such that the controller is operable to: drive a first said airflow device at a predetermined rate to generate an airflow through the first said airflow device and out of electronic equipment having a particulate filter, monitor an airflow through a second airflow device into the electronic equipment, and generate an indication of a performance characteristic of the particulate filter based on the monitoring of the airflow through the second airflow device

### BRIEF DESCRIPTION OF THE DRAWINGS

For a better understanding of the present disclosure, and to show more clearly how it may be carried into effect, reference will now be made, by way of example, to the following drawings, in which:

FIG. 1 illustrates a radio access node according to an example;

FIG. 2 is schematic of a control architecture for cooling fans in a radio access node according to an example;

FIGS. 3 and 4 illustrate monitoring airflow through an airflow device in a radio access node to determine particulate filter clogging according to an example;

FIG. 5 is a flow chart illustrating process steps in a method for monitoring airflow devices according to an example;

FIGS. 6A-6D illustrate monitoring airflow through an airflow devices in a radio access node to determine clogging in different selected particulate filters according to an example; and

FIG. 7 illustrates an apparatus for monitoring airflow devices according to an example.

### DETAILED DESCRIPTION

Examples of the present disclosure propose monitoring for a reduced airflow condition corresponding to a performance characteristic or clogging of a particulate filter in a radio access node or other electronic device. One of a plurality of cooling fans or similar airflow devices is selected for monitoring airflow therethrough whilst the other fans are driven at a set level, for example full speed. The speed of the selected fan is monitored to indicate airflow through this fan which can be used to indicate the state of clogging of a particulate filter. Airflow through the filter is reduced by clogging and this results in additional airflow needing to be drawn through the selected fan which can be detected and used to characterize the state of the particulate filter. As appropriate control and monitoring of existing fans can be used to detect particulate filter clogging, no additional hardware is required, simplifying design of the radio access node.

Many radio access nodes use fans with built in tachometers which can provide a direct indication of airflow through the selected fan. In other examples, induced voltage and current may be monitored for very simple fans. The airflow through a selected fan may be characterized for different levels of clogging of a particulate filter in an electronic device such as a radio access node so that the monitored airflow through a selected device can be used to provide an indication of a performance characteristic or clogging of the particulate filter in situ. In some examples, fans may be selected in sequence for monitoring airflow, which may provide greater accuracy of the current performance characteristic of particulate filter. In some configurations, fans may be selected to determine the performance characteristics of individual particulate filters.

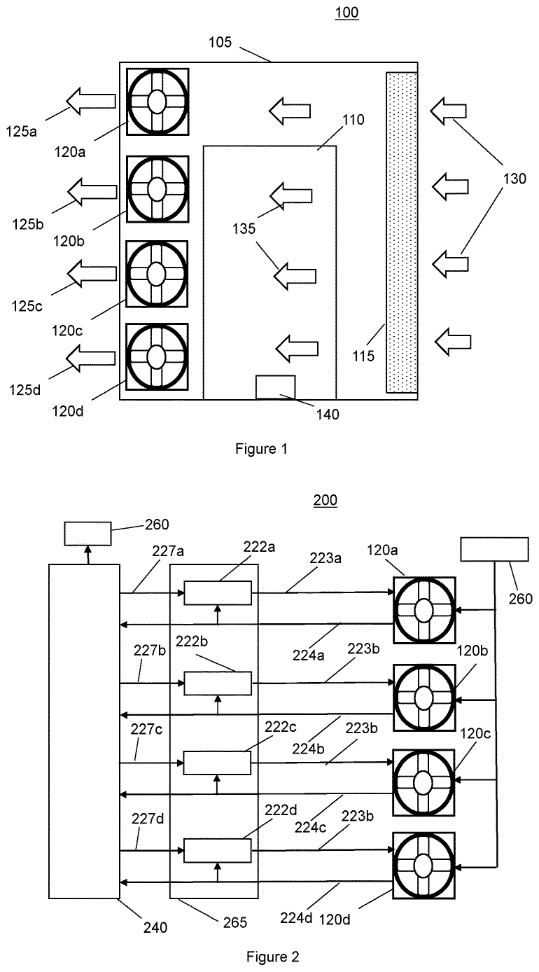

FIG. 1 illustrates electronic equipment 100 according to an example. The electronic equipment may be a radio access node 100 comprises a housing 105, a circuit board 110, a particulate filter 115 and a plurality of airflow devices 120a-120d. The circuit board 110 may hold a number of electronic components such as integrated circuits, inductors, transformers, capacitors, and other parts which generate heat when operating. The circuit board also holds an apparatus 140 for operating the plurality of airflow devices as described in more detail below.

The particulate filter 115 covers an airflow ingress port or ports in the housing 105 of the electronic equipment 100 to allow external air to be drawn into the housing 105. The airflow devices 120a-120d are housed in or about one or more egress ports in the housing 105 which allow air inside the housing to be evacuated to outside the housing. The airflow devices may be driven to air into the housing as indicated at 130, through the particulate filter 115 and forced outside as indicated by 125a-125d. The movement of air generated airflows 135 across the circuit board 110 and about the electronic components to remove heat from these parts. The airflow devices may be operated at different levels to provide different levels of cooling of the electronic components, for example based on a temperature sensor in the housing 105.

The particulate filter 115 may be a fine metallic mesh, photo-etched sheet metal, a sheet of fabric or any suitable material which prevents the ingress of dust and other small particles into the housing of the electronic components. The filter will often retain a proportion of the particles and therefore over time the filter will become progressively more blocked or clogged with a smaller area available for allowing airflow into the housing. This in turn reduces the amount of airflow 135 passing over the circuit board 110 for a given airflow level. This may reduce the effectiveness of the thermal management of the electronic equipment 100 potentially leading to early failure of one or more components. The particulate filter may be associated with a performance characteristic corresponding to an amount or level of clogging or a level of airflow compared with a nominal (unclogged) level.

The airflow devices 120a-120d may comprise individually controllable electrically driven fans. These may be provided in a modular fan tray for ease of replacement.

FIG. 2 illustrates a control architecture 200 for normal operation of fans according to an example. Each fan 120a-120d is controlled by a respective pulse wave modulation (PWM) drive signal 223a-223d from a drive controller 222a-222d. The drive controllers may be provided as a single drive controller 265 with multiple channels each for a respective fan. Each fan outputs a tachometer signals 224a-224d indicating the speed of the fan. The tachometer signals are used by the drive controllers 222a-222d in respective control loops to control the speed of the fans 120a-120d according to a respective set level 227a-227d. The settings may be respective voltages corresponding to wanted fans speeds and are provided by an apparatus 240 for operating the fans 120a-120d. The fans may be supplied by a common power supply 260.

In an example, the apparatus 240 also receives the tachometer signals 224a-224d and uses these together with controlling the fans to provide an indication 260 of a performance characteristic of the particulate filter 115. The indication 260 may be a signal indicating that the filter is partially clogged over a wanted threshold and signaling that the particulate filter needs replacing. The indication may provide an estimation of a percentage blocked which may then be used by an operator to make a decision on when to replace the particulate filter. The indication may also or alternatively provide a visual indication such as an LED on the exterior of the housing 105.

In alternative examples, different types of fans may be used, including simple DC fans in which their speed is controlled by input voltage. An indication of speed may be provided by monitoring induced voltage in non-driven fans.

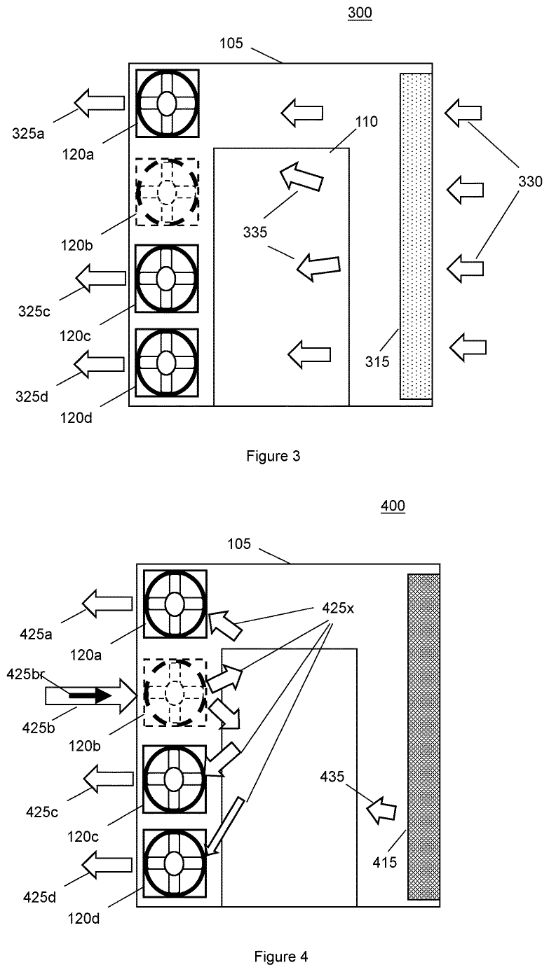

Reference is made to FIGS. 3-5 to describe a method of generating an indication of a performance characteristic of a particulate filter according to an example. The method 500 may be implemented by the apparatus 140, 240 of FIG. 1 or 2, or by any other suitable apparatus.

At 505, the method 500 drives all fans 120a-120d to generate sufficient airflow around electronic components of electronic equipment 100 to ensure proper thermal management. This may be implemented using one or more temperature sensors located in different parts of the electronic equipment 100. A suitable algorithm may then be used to control drive signals to the fans. For example, if any one temperature sensor indicates a temperature above a threshold and/or the average of all temperature sensors is above another threshold, then the level of the fans may be increased to increase airflow 130. More sophisticated approaches may be used, such as characterizing or modeling the thermal dynamics of the electronic equipment and using artificial intelligence control of the fans to maintain appropriate temperatures.

As noted previously, the accuracy of this thermal management may be affected by clogging of the particulate filter 115. Therefore at 510, the method determines whether to enter a test mode. This may simply be based on a regular testing schedule or may be based on temperature profiles of the electronic equipment. For example, if a low work rate of the electronic device still results in elevated temperatures inside the housing 105, then the test mode may be entered.

At 515, the test mode of the fans 120a-120d is configured. In the example of FIG. 3, three fans 120a, 120c, 120d are driven and one fan 120b is not driven. The non-driven fan 120b is shown in dashed outline. The driven fans are driven at a predetermined level which may be the maximum level in one example. The airflows 335 through the electronic equipment 300 may be different compared with those of all four fans being driven with a greater outflow 325a, 325c, 325d through the three driven fans and no outflow through the non-driven fan 120b.

The driven fans 120a, 120c, 120d driven at maximum speed may correspond to respective airflow rates 325a, 325c, 325d and together a combined airflow rate. When the particulate filter 115 is not clogged, this combined airflow rate may be substantially equal to the rate of airflow 330 through particulate filter 115. In this case, no additional airflow is required to enter the housing 105 in order to balance the airflow pushed out of the housing by the driven fans 120a, 120c, 120d. However, when the particulate filter 415 is clogged as illustrated in FIG. 4, the filter may not allow enough airflow into the housing to balance the airflow forced out of the housing by the driven fans. This will reduce the pressure inside the housing causing airflow to enter the housing via the non-driven fan 120b. The airflow 425b passing through the fan 120b combines with any airflow 435 through the particulate filter to match the airflow pushed out by the driven fans—these airflow components are illustrated generally at 425x.

The greater the level of clogging of the particulate filter 415, the less airflow 435 this allows into the housing and therefore the greater the airflow 425b required through the non-driven fan 120b required to match the outflows through the driven fans 120a, 120c, 120d. Therefore, the airflow 425b through the non-driven fan 120b can provide an indication of a performance characteristic of the particulate filter 415—for example how clogged this is.

The airflow 425b through the non-driven fan 120b will cause the non-driven fan 120b to rotate. The rate of this rotation may be dependent on the level of airflow through the non-driven fan—this level of airflow may be the rate of airflow 425br.

At 520, the method monitors the tachometer signal 244b of the non-driven fan which provides the speed of rotation of the non-driven fan 120b. The fan speed of the non-driven may be monitored for a predetermined period of time, for example 60 seconds, sufficient to enable this effect to be established and recorded. In other examples, different signals may be monitored to infer the airflow forced past the non-driven fan, such as the voltage of a simple DC fan. Some fans may be installed with external optical monitoring sensors or other devices for sensing fan speed.

At 535, the method determines whether there are more test modes. This may include selecting a different fan, for example 120d, as the non-driven fan and then driving the other fans 120a-120c and monitoring the speed of the other non-driven fan. This may be repeated for all available fans 120a-120d in a sequence. Averaging the detected speeds for all fans may provide a more accurate indication of clogging.

At 540, the method generates an indication of the level of clogging or another performance characteristic of the particulate filter. The speed(s) of the non-driven fan(s) is used to derive the indication. A correlation between non-driven fan speed and the level of clogging of the particulate filter may be derived experimentally and then applied to the speeds detected in practice. If the level of clogging is above a threshold, then an alarm may be sent to an operator of the electronic equipment 100 indicating that the particulate filter needs replacing. Such an indication may be based on one or more of the following: averaging the rates of airflow through the second airflow devices; determining whether one or more of the rates of airflow through the second airflow devices exceeds a threshold; applying the rates of airflow through the second airflow devices to a trained artificial intelligence.

Alternatively, the indication of a performance characteristic may simply be an estimated level of clogging which is provided to the operator for follow up action is determined necessary.

The method then returns to 505 corresponding to normally operational mode where all fans are driven according to the colling needs of the electronic equipment.

Various alternatives to the above described examples are possible. For example, driven fans 120a, 120c, 120d may be driven at a level which is less than the maximum in a test mode. Different test modes at different driven levels may be used. The non-driven fan 120b may actually be driven at a reduced level compared with the driven fans so that it still results in a net inflow of airflow through this fan during testing. The non-driven fan may alternatively be driven in reverse, with additional inflow above what would be expected by its reverse drive being attributed to inflow caused by clogging of the particulate filter.

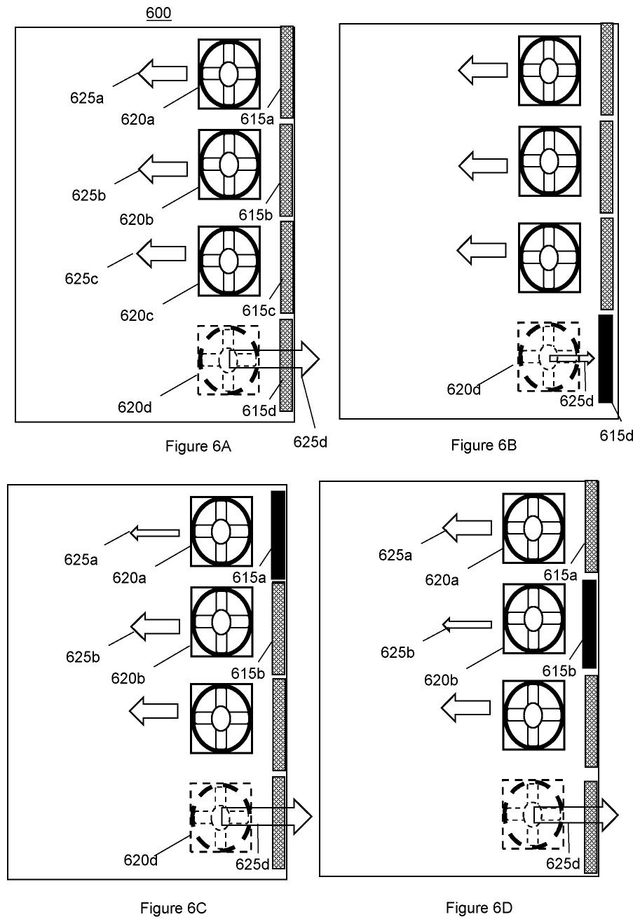

Any number of two or more fans may be employed, and more than one particulate filter may be used. In some examples, more than one fan may not be driven and its speed or other airflow related parameter monitored. In some configurations, it is possible to determine the level of clogging of individual particulate filters as illustrated in FIGS. 6A-6D. This illustrates an alternative configuration of an electronic device having four fans 620a-620d respective adjacent particulate filters 615a-615d. The airflows through each fan are indicated by arrows 625a-625d respectively.

With fan 620d selected as the non-driven fan, the airflow 625d is through the fan 620d and out of the electronic equipment 600 through the adjacent particulate filter 615d. With the driven fans 615a-615c, the respective airflows 625a-625c are into the electronic equipment through the particulate filters 615a-615c and adjacent fans 620a-620c.

FIG. 6A illustrates the situation when all particulate filters 615a-615d are unclogged. FIG. 6B illustrates the situation when the particulate filter 615d adjacent the non-driven fan 620d is clogged—this is indicated by the darker shading of this filter. In this situation, the airflow 625d through the non-driven fan 620d and the clogged particulate filter 615d is reduced compared with the situation of FIG. 6A. The airflows 625a-625c are substantially the same as those of the situation in FIG. 6A.

FIG. 6C illustrates the situation where a particulate filter 615a not adjacent the non-driven fan 620d is clogged. In this situation the airflow 625a through the particulate filter 615a and the adjacent driven fan 620a are reduced compared with the situation in FIG. 6A, and the airflow 625d is substantially the same as the situation in FIG. 6A. FIG. 6D illustrates a similar situation where another particulate filter 615b not adjacent the non-driven fan 620d is clogged. In this situation the airflow 625b through the particulate filter 615b and the adjacent driven fan 620b are reduced compared with the situation in FIG. 6A, and the airflow 625d is substantially the same as the situation in FIG. 6A.

By monitoring airflow 620d of the non-driven fan 620d, it is possible to determine the adjacent particulate filter 615d is clogged, as the rate of airflow or the speed of the fan indicated by a tachometer signal will be lower. The level of clogging of the adjacent particulate filter 615d may be characterized experimentally.

The level of clogging of the other particulate filters 615a-615c may also be determined by selecting their respective adjacent fans 620a-620c as the non-driven fan, with the other fans being driven. Cycling through each fan as the non-driven fan may then be performed to determine individual levels of clogging of each particulate filter 615a-615d.

If one of the particulate filters 615X, 615Y is clogged but the other particulate filter 615Y, 615X, then the outflow 625a-625c generated by driving the other fans 420a-420c will mostly be provide by a combination of airflow 635 through the unclogged particulate filter 615X or 615Y and airflow 625d through the non-driven fan 420d. When the clogged particulate filter 615X is not near the non-driven fan 420d, the combined airflow within the housing becomes fairly uniform as the two inflows are spaced apart allows the airflows to evenly distribute through the driven outflow fans 420a-420c. However, if the clogged particulate filter 615Y is adjacent the non-driven fan 420d, more airflow will be drawn through the non-driven fan 420 as

[symbol]

The closer the distance between the non-driven fan and the clogged filter, the greater the accuracy of clogging level estimation of the nearby filter. In practice a distance of less than 15 mm between a particulate filter and an adjacent fan will enable an estimation of the level of clogging of the particulate filter.

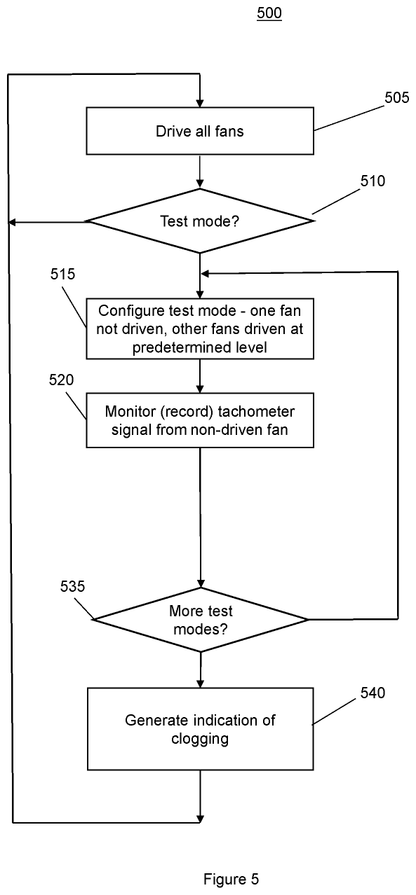

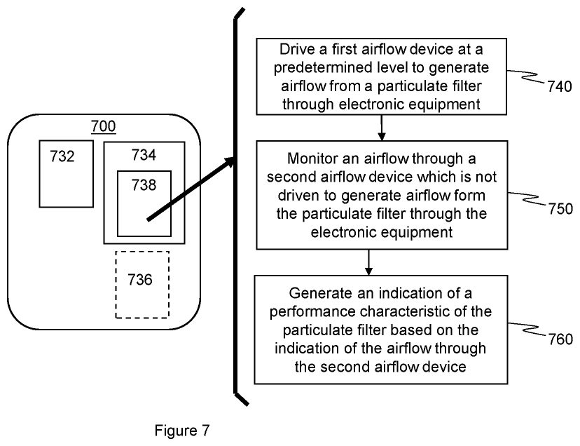

FIG. 7 illustrates an apparatus 700 that may be adapted to implement the operating of airflow devices. The apparatus 700 comprises a processor 732 and memory 734 containing executable instructions 738. The executable instructions 738 may be in the form of a computer program and may include instructions for executing one or more methods, such as the method 500 of FIG. 5. In some examples, the processor or processing circuitry 732 may include one or more microprocessors or microcontrollers, as well as other digital hardware, which may include digital signal processors (DSPs), special-purpose digital logic, etc. The processor or processing circuitry may be implemented by any type of integrated circuit, such as an Application Specific Integrated Circuit (ASIC), Field Programmable Gate Array (FPGA) etc. The memory 734 may include one or several types of memory suitable for the processor, such as read-only memory (ROM), random-access memory, cache memory, flash memory devices, optical storage devices, solid state disk, hard disk drive etc.

At 740, a first airflow device is driven at a predetermined level such as its maximum rated level or speed. The first airflow device may be a fan and is arranged to allow airflow into or out of electronic equipment. Upon being driven, the first airflow device generates an airflow from a particulate filter and through the electronic device.

At 750, an airflow through a second airflow device is monitored. The second airflow device is also arranged to allow airflow into or out of the electronic equipment. The second airflow device is not driven to generate airflow from the particulate filter through the electronic equipment. If the particulate filter is unclogged, little or no airflow will be drawn into the electronic equipment through the second airflow device. However, if the particulate filter is clogged, airflow will be drawn through the second airflow device. A parameter such as airflow rate can be directly or indirectly monitored, for example using a tachometer signal from the fan.

At 760, an indication of a performance characteristic of the particulate filter is generated. This is based on the airflow through the second airflow device. For example, a fan speed above a threshold may indicate that the particulate filter is so clogged that it requires replacement.

Examples may provide a number of advantages including providing a simple cost effective solution to the problem of detecting particulate filter clogging. Examples avoid adding hardware to detect particulate filter clogging in electronic equipment. For example, this functionality may be implemented using a simple software update on existing hardware. Existing fan functionality such as a tachometer signal may be easily integrated. This additional functionality therefore does not impact the MTBF of the electronic equipment. This approach is effective irrespective of the location of the particulate filter or filters, or of electronic components within the electronic equipment. The time required for the testing mode for particulate filter clogging is short which does not impact on the thermal stabilization of the electronic equipment. This is further enhanced by driving all the fans except the one(s) used for monitoring inflow.

Whilst the electronic equipment has been described as a radio access node, other examples may use other telecommunications equipment or indeed any other electronic equipment.

The methods of the present disclosure may be implemented in hardware, or as software modules running on one or more processors. The methods may also be carried out according to the instructions of a computer program, and the present disclosure also provides a computer readable medium having stored thereon a program for carrying out any of the methods described herein. A computer program embodying the disclosure may be stored on a computer readable medium, or it could, for example, be in the form of a signal such as a downloadable data signal provided from an Internet website, or it could be in any other form.

It should be noted that the above-mentioned examples illustrate rather than limit the disclosure, and that those skilled in the art will be able to design many alternative embodiments without departing from the scope of the appended claims. The word “comprising” does not exclude the presence of elements or steps other than those listed in a claim, “a” or “an” does not exclude a plurality, and a single processor or other unit may fulfil the functions of several units recited in the claims. Any reference signs in the claims shall not be construed so as to limit their scope.

1. A method of monitoring airflow devices, the method comprising:
driving a first airflow device at a predetermined level to generate an airflow through the first airflow device and out of electronic equipment having a particulate filter, the particulate filter covering an airflow ingress port or ports in the housing of the electronic equipment, and the airflow devices are housed in or about one or more egress ports in the housing;
monitoring a parameter associated with an airflow through a second airflow device into the electronic equipment;
not driving the second airflow device to generate an airflow out of the electronic equipment; and
generating an indication of a performance characteristic of the particulate filter based on the monitoring of the airflow through the second airflow device.

2. (canceled)

3. The method of claim 1, wherein the electronic equipment has a second particulate filters, the first and the second particulate filters being located within a predetermined distance of a respective airflow device, and the method comprising generating the indication of a performance characteristic for a selected one of the particulate filters based on a selection the airflow device within the predetermined distance of the selected particulate filter as the second airflow device.

4. The method of claim 1, comprising selecting an individual airflow device from the plurality of airflow devices as the second airflow device according to a sequence, and wherein the indication of a performance characteristic of the particulate filter is generated based on the airflow of the individual airflow device when selected as the second airflow device.

5. (canceled)

6. The method of claim 4, wherein monitoring an airflow through a second airflow device into the electronic equipment comprises monitoring a rate of airflow through the second airflow device and generating an indication of a performance characteristic of the particulate filter comprises using one or more of the following calculations: averaging the rates of airflow through the second airflow devices; determining whether one or more of the rates of airflow through the second airflow devices exceeds a threshold; applying the rates of airflow through the second airflow devices to a trained artificial intelligence.

7. The method of claim 1, wherein the airflow devices are fans at least one of which is operable to generate a tachometer signal indicative of a rate of airflow through the second airflow device.

8. The method of claim 7, wherein the first airflow device is driven at a maximum rated level.

9. The method of claim 1, wherein generating an indication of a performance characteristic of the particulate filter comprises one or more of the following: an indication that the particulate filter needs replacing; an indication of a level of occlusion of the particulate filter.

10. The method of claim 1, comprising in a cooling mode driving all of the airflow devices dependent on a temperature measurement of the electronic apparatus.

11. An apparatus for monitoring airflow devices in electronic equipment, the apparatus comprising a processor and a memory, the memory containing instructions executable by the processor such that the controller is operable to:
drive a first airflow device at a predetermined rate to generate an airflow through the first airflow device and out of electronic equipment having a particulate filter, the particulate filter covering an airflow ingress port or ports in the housing of the electronic equipment, and the airflow devices are housed in or about one or more egress ports in the housing;
monitor a parameter associated with an airflow through a second airflow device into the electronic equipment;
not drive the second airflow device to generate an airflow out of the electronic equipment; and
generate an indication of a performance characteristic of the particulate filter based on the monitoring of the airflow through the second airflow device.

12. (canceled)

13. The apparatus of claim 11, wherein the electronic equipment has a second particulate filter, the first and second particulate filters being located within a predetermined distance of a respective airflow device, and the apparatus is operable to generate the indication of a performance characteristic for a selected one of the particulate filters based on a selection of the airflow device within the predetermined distance of the selected particulate filter as the second airflow device.

14. The apparatus of claim 11, operable to select an individual airflow device from the plurality of airflow devices as the second airflow device according to a sequence, and to generate the indication of a performance characteristic of the particulate filter based on the airflow of the individual airflow device when selected as the second airflow device.

15. (canceled)

16. The apparatus of claim 14, wherein monitoring an airflow through a second airflow device into the electronic equipment comprises monitoring a rate of airflow through the second airflow device and the apparatus operable to use one or more of the following calculations to generate an indication of a performance characteristic of the particulate filter comprises: averaging the rates of airflow through the second airflow devices; determining whether one or more of the rates of airflow through the second airflow devices exceeds a threshold; applying the rates of airflow through the second airflow devices to a trained artificial intelligence.

17. The apparatus of claim 11, operable to monitor a tachometer signal indicative of a rate of airflow through the second airflow device.

18. The apparatus of claim 11, wherein the first airflow device is driven at a maximum rated level.

19. The apparatus of claim 11, wherein the indication of a performance characteristic of the particulate filter comprises one or more of the following: an indication that the particulate filter needs replacing; an indication of a level of occlusion of the particulate filter.

20. The apparatus of claim 11, operable in a cooling mode to drive all of the airflow devices dependent on a temperature measurement of the electronic apparatus.

21. A cooling system for electronic equipment having a particulate filter, the cooling system comprising a plurality of airflow devices and an apparatus, the apparatus comprising a processor and a memory, the memory containing instructions executable by the processor such that the controller is operable to:
drive a first airflow device of the plurality of airflow devices at a predetermined rate to generate an airflow through the first airflow device and out of electronic equipment having a particulate filter, the particulate filter covering an airflow ingress port or ports in the housing of the electronic equipment, and the airflow devices are housed in or about one or more egress ports in the housing;
monitor a parameter associated with an airflow through a second airflow device of the plurality of airflow devices into the electronic equipment;
not drive the second airflow device to generate an airflow out of the electronic equipment; and
generate an indication of a performance characteristic of the particulate filter based on the monitoring of the airflow through the second airflow device.

22. The cooling arrangement of claim 21, wherein the particulate filter and the cooling arrangement are comprised in electronic equipment.

23. (canceled)

24. (canceled)

25. The method of claim 3, comprising selecting an individual airflow device from the plurality of airflow devices as the second airflow device according to a sequence, and wherein the indication of a performance characteristic of the particulate filter is generated based on the airflow of the individual airflow device when selected as the second airflow device.

26. The method of claim 3, wherein the airflow devices are fans at least one of which is operable to generate a tachometer signal indicative of a rate of airflow through the second airflow device.
